(19) United States
(12) Patent Application Publication
(10) Pub. No.: US 2019/0123035 A1
(43) Pub. Date: Apr. 25, 2019

(54) METHOD OF PERFORMING DIE-BASED HETEROGENEOUS INTEGRATION AND DEVICES INCLUDING INTEGRATED DIES

(71) Applicant: Samsung Electronics Co., Ltd., Gyeonggi-do (KR)

(72) Inventor: Daniel N. Carothers, Lucas, TX (US)

(21) Appl. No.: 15/880,349

(22) Filed: Jan. 25, 2018

Related U.S. Application Data
(60) Provisional application No. 62/574,712, filed on Oct. 19, 2017.

(51) Int. Cl. H01L 25/00; H01L 21/78; H01L 21/306; H01L 23/00; H01L 23/538; H01L 25/18

(52) U.S. Cl. CPC H01L 25/50; H01L 2224/83203; H01L 21/30612; H01L 21/30621; H01L 24/32; H01L 23/5386; H01L 25/18; H01L 24/83; H01L 2224/32145; H01L 2924/10253; H01L 2924/1032; H01L 2224/27416; H01L 2224/8392; H01L 2224/8389; H01L 21/7806

(57) ABSTRACT

A method for integrating heterogeneous elements with elements residing on a target wafer is described. A source die including a compound semiconductor substrate, an etch stop layer and at least one active semiconductor element is provided. The etch stop layer is between the active semiconductor element(s) and the substrate. The etch stop layer is resistant to a plasma etch for the substrate. A bonding agent is provided on a surface of the target wafer. The source die is aligned to and placed on the part of the surface of the target wafer such that the active semiconductor element(s) are between the target wafer's surface and the substrate. The bonding agent is between the source die and the surface of the target wafer. The source die is bonded to the target wafer using the bonding agent. The substrate of the source die is removed, the removal includes performing the plasma etch.

### CROSS-REFERENCE TO RELATED APPLICATIONS

This application claims the benefit of provisional Patent Application Ser. No. 62/574,712, filed Oct. 19, 2017, entitled “METHOD FOR DIE BASED HETEROGENEOUS INTEGRATION”, assigned to the assignee of the present application, and incorporated herein by reference.

### BACKGROUND

Integrated devices including semiconductors and other materials, may have improved performance and/or functionality. For example, photonic circuits may be desired to be integrated with a number of semiconductor technologies including but not limited to CMOS, BiCMOS and silicon microelectromechanical systems (MEMS). III-V materials and other active semiconductor materials maintain advantages in regard to photonics, ferromagnetics, RF and power applications. Consequently, III-V materials are desired to be used for photonics circuits. Silicon maintains the ability to implement complex processing and interface circuits that often are required for the application of these “other” material systems. It is desirable, therefore, to integrate different active heterogeneous elements such as III-V materials with silicon.

Currently, wafer bonding approaches are used to integrate these materials. In such technologies, entire wafers are bonded together. However, many devices incorporating compound semiconductor (CS) materials, such as III-V materials, are grown on wafers smaller than silicon wafers. For example, GaAs wafers may be used for CS technologies. GaAs wafers are typically one hundred and fifty or two hundred millimeters in diameter. Typical silicon wafers are three hundred millimeters in diameter. Consequently, multiple CS wafers are used to cover a single silicon wafer. Even if the wafers are same size for bonding, generally seventy-five percent to ninety-five percent of wafer bonded III-V materials are etched away during manufacturing. Consequently, wafer bonding is an inefficient mechanism for integrating CS materials with silicon.

Other technologies employ molecular bonding to combine materials. These technologies generally require ultra-fine control over the planarity of the surfaces to ensure that the surface modifications or interactions that occur to bond wafer or die to a target substrate are uniform in nature and that the bond strength allows follow on processing. These approaches also generally require expensive application of polishing technologies, which can increase cost and negatively impact yield.

Consequently, an improved mechanism for combining active semiconductor circuit elements with silicon is desired.

### BRIEF SUMMARY OF THE INVENTION

A method for integrating heterogeneous elements with circuit elements residing on a target wafer and the device so formed are described. A source die is provided. The source die includes a compound semiconductor (CS) substrate such as GaAs, an etch stop layer and at least one active semiconductor element formed on the CS substrate. The etch stop layer is between the active semiconductor element(s) and the CS substrate. The etch stop layer is resistant to a plasma etch for the CS substrate, such as a SF₆/BCl₄ or SF₆/SiCl₄ plasma etch for GaAs. A bonding agent is provided on at least a portion of a surface of the target wafer. The source die is aligned to and placed on the portion of the surface of the target wafer such that the active semiconductor element(s) are between the surface of the target wafer and the CS substrate. At least part of the bonding agent is between the source die and the surface of the target wafer. The source die is bonded to the surface of the target wafer using the bonding agent. The substrate of the source die is removed. Removing the substrate includes using the plasma etch to which the etch stop layer is resistant. Consequently, at least a portion of the etch stop layer and active semiconductor elements remain bonded to the target substrate.

The method described herein may integrate heterogeneous elements with high interconnect density, provide a back end of line (BEOL) integration that does not interfere with fabrication of front end of line (FEOL) electronics, provide tight coupling with the electronics, allow for integration with deposited photonic structures in the BEOL, provide wafer level application that can be applied to various sized ASICs or ROICs, allow for metal contact structure to be made to the back side of the heterogeneous devices, and allow for deposited waveguides to be added after removal of the substrate.

### BRIEF DESCRIPTION OF SEVERAL VIEWS OF THE DRAWINGS

FIG. 1 is a flow chart depicting an exemplary embodiment of a method for integrating heterogeneous elements in a semiconductor device.

FIGS. 2A-2D depict portions of an exemplary embodiment of a semiconductor device during fabrication.

FIG. 3 is a flow chart depicting another exemplary embodiment of a method for integrating heterogeneous elements in a semiconductor device.

FIGS. 4A and 4B depict plan and sides views of an exemplary embodiment of a semiconductor device that integrates heterogeneous elements.

FIG. 5 is an exemplary embodiment of a semiconductor device that integrates heterogeneous elements.

FIG. 6 is an exemplary embodiment of a semiconductor device that integrates heterogeneous elements.

### DETAILED DESCRIPTION OF THE INVENTION

The exemplary embodiments relate to devices that integrates heterogeneous elements, such as semiconductor elements and active semiconductor elements, including but not limited to III-V materials and components made with these materials. The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular methods and systems provided in particular implementations. However, the methods and systems will operate effectively in other implementations.

Phrases such as “exemplary embodiment”, “one embodiment” and “another embodiment” may refer to the same or different embodiments as well as to multiple embodiments. The embodiments will be described with respect to systems and/or devices having certain components. However, the systems and/or devices may include more or fewer components than those shown, and variations in the arrangement and type of the components may be made without departing from the scope of the invention. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

A method for integrating heterogeneous elements on a target wafer and the device so formed are described. A source die including a compound semiconductor (CS) substrate such as GaAs, an etch stop layer and at least one active semiconductor element is provided. The etch stop layer is between the active semiconductor element(s) and the CS substrate. The etch stop layer is resistant to a plasma etch for the CS substrate. A bonding agent is provided on at least a portion of a surface of the target wafer. The source die is aligned to and placed on the portion of the surface of the target wafer such that the active semiconductor element(s) are between the surface of the target wafer and the CS substrate. At least part of the bonding agent is between the source die and the surface of the target wafer. The source die is bonded to the surface of the target wafer using the bonding agent. The substrate of the source die is removed, which includes using the plasma etch to which the etch stop layer is resistant.

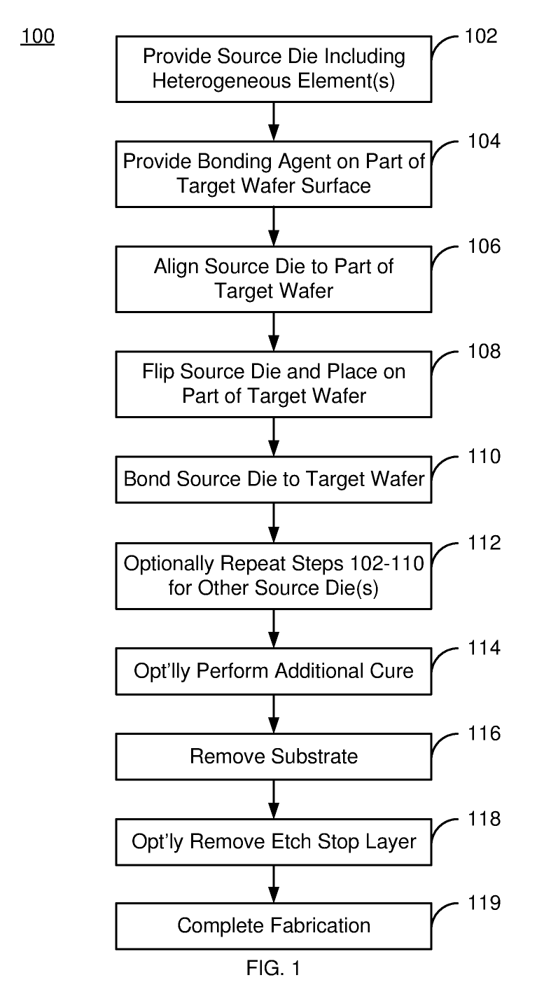

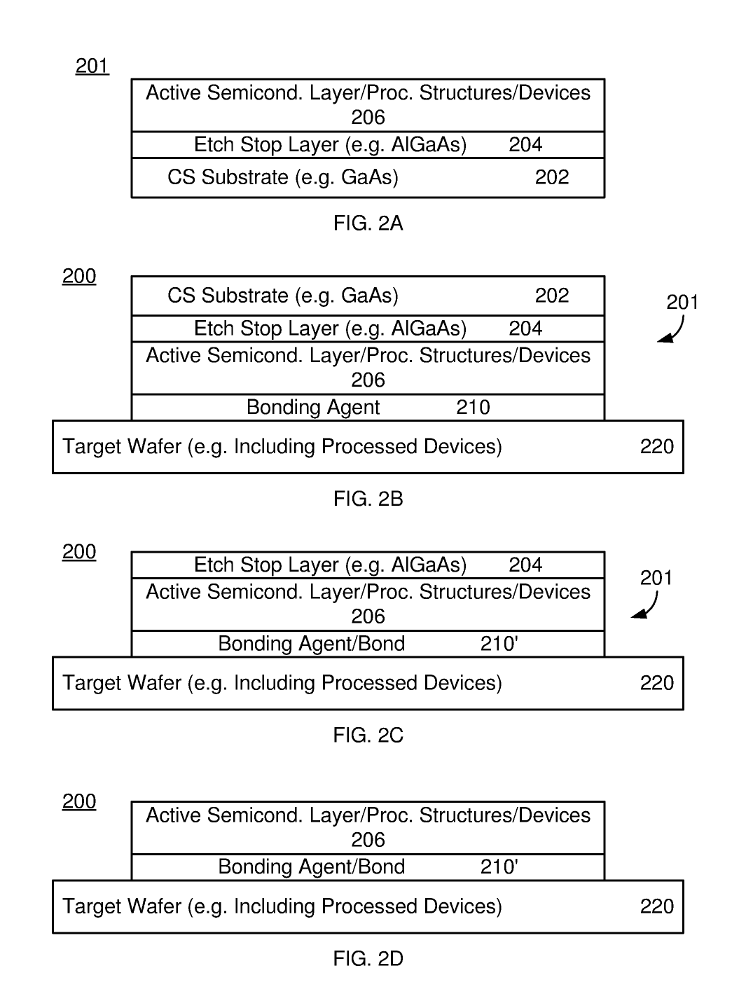

FIG. 1 is a flow chart depicting an exemplary embodiment of a method 100 for integrating heterogeneous elements in a semiconductor device. For simplicity, some steps may be omitted, performed in another order and/or combined. Further, the method 100 may start after other steps in forming the semiconductor device have been performed. More specifically, the method 100 integrates silicon elements with active semiconductor elements formed on a CS wafer such as GaAs. As used herein an active semiconductor element is an element not typically formed on a silicon wafer. Such active semiconductor elements may be grown, epitaxially or otherwise, on CS wafers such as GaAs. For example, an active semiconductor element includes but may not be limited to elements such as III-V materials and components including III-V materials, Ill-Nitrides and components including III-Nitrides such as Ga-N based devices. III-V materials that may be epitaxially grown for the active semiconductor element include BN, AlN, GaN, InN, TIN, Ge, BP, AlP, GaP, InP, TIP, CdSe, BAs, AlAs, GaAs, InAs, TlAs, CdTe, BSb, AlSb, GaSb, InSb, TlSb, CdAs, BBi, AlBi, GaBi, InBi, TIBi, CdS, MoSe, MoS, MnAs, GaMnAs, InMnAs, ZnSe, CdMnTe, BaTiO₃, SrTiO₃, Bi₂Tie₃, CdZnTe, ZnS, HgCdTe, HgZnTe, ZnMgSSe, BiSe, BiTe, ZnO, AlGaAs, InGaAs, AlInAs, AlInSb, GaAsN, PbSe, GaAsP, GaAsSb, AlGaN, AlGaP, InGaN, PbTe, InAsSb, InGaSb, AlGaInP, AlGaAsP, InGaAsP, PbS, InAsSbP, AlInAsP, AlGaAsN, InGaAsN, InAlAsN, SnTe, GaAsSbN, GaInNAsSb, GaInAsSbP, SiGe, GaAsO, PbSnTe, GaAsBi, GaBiNAs, InGaBiAs, InGaBi, InGaBiN and GaSbBi. Other examples of active semiconductor elements include heterostructures, homojunctions, quantum wells, quantum dots, quantum wires, and other analogous structures. Thus, the active semiconductor element may include any elements not typically grown on the target wafer, but which are generally grown on the GaAs wafer for the source die. Further, such elements may be single layers, multilayers, or devices fabricated from one or more layer(s). FIGS. 2A-2D depict portions of an exemplary embodiment of a semiconductor device 200, such as a CMOS device, during fabrication using the method 100. For simplicity, not all components are shown in FIGS. 2A-2D and FIGS. 2A-2D are not to scale. Consequently, the method 100 is described in the context of the semiconductor device 200.

A source die is provided, via step 102. Step 102 includes fabricating an etch stop layer and active semiconductor element(s) on a CS wafer. The CS substrate may include a GaAs wafer or another analogous substrate. A GaAs wafers are preferred because of their epitaxial flexibility and relative ease of substrate removal. The etch stop layer is between the active semiconductor element(s) and the CS substrate. The etch stop layer is resistant to a plasma etch that can be used in removing the CS substrate. For example, the etch stop layer may be an AIGaAs layer that is resistant to GaAs plasma etches, such as SF₆/BCl₄ or SF₆/ SiCl₄ plasma etches. The active semiconductor elements are described above. For example, III-V materials may be grown epitaxially on the etch stop layer of a GaAs wafer. The layers may be very thin and, in some embodiments, may be processed to form devices. The source die may be singulated from the wafer, for example via dicing, a scriber or laser. In some embodiments, a layer such as silicon dioxide may be deposited on the source wafer before the die is singulated. Such a layer may improve bonding of the source die and may protect the active semiconductor element(s) during singulation. An additional protective layer may also be deposited on the source die to reduce damage during singulation. The source die thus includes the CS substrate, the etch stop layer and at least one active semiconductor element.

FIG. 2A depicts the source die 201 to be used in the semiconductor device 200. Thus, a CS substrate 202 such as GaAs, an etch stop layer 204 such as AIGaAs and the active semiconductor element(s) 206 are shown. The active semiconductor element(s) 206 may include one or more layers that may be grown on the substrate 202. In some embodiments, the active semiconductor element(s) 206 may include layers, structures, devices and/or portions thereof grown on the substrate 202. In some embodiments, the active semiconductor element(s) 206 may be any material and/or structure fabricated on the etch stop layer 204. The source die 201 is smaller than the target wafer to which the source die is to be bonded.

A bonding agent is provided on a surface of a target wafer, via step 104. The target wafer may be a Si wafer on which some semiconductor devices have already been fabricated. For example, the target wafer may include CMOS elements, BiCMOS elements, MEMS elements or portions thereof that have already been formed. A thin oxide layer may optionally be provided on the surface of the target wafer prior to the bonding agent to improve bonding. In some embodiments, the bonding agent is a spin-on glass (SOG). The SOG may be applied via inkjet printing, nano-dispense tools, or spun on. Inkjet printing and nano-dispense tools may be desired because of their ability to apply SOG to a well-defined area. In some embodiments, the SOG is at least one hundred nanometers thick and not more than five hundred nanometers thick. Other thicknesses are, however, possible. Other flowable bonding agents and/or application methods may be used. The bonding agent covers at least the portion of the surface of the target wafer to which the source die 201 is desired to be bonded. In some embodiments, other portions of the surface of the target wafer may be covered in the bonding agent. Although the entire surface of the target wafer might be covered in the bonding agent, this is generally not desired because of the possibility of cracking and difficulty in placing the bonding agent in a controlled manner. Because the flowable bonding agent is added to the surface of the target wafer in step 104, the surface need not be planarized prior to bonding. Instead, surface tension of the bonding agent pulls and holds the material over large topographic variations. During the bonding process, the displacement of the bonding agent allows a bond-line to be defined and maintained.

The source die 201 is aligned to a desired portion of the surface of the target wafer, via step 106. The desired location of the source die may be on a region of the target wafer corresponding to a single die of the semiconductor device 200, may include multiple regions/dies of the target wafer and/or may lie across scribe streets on the surface of the target wafer. The alignment in step 106 also allows existing alignment features on the target wafer to be used for precision alignment of the structure(s) on the source die 201 to existing structures on the target wafer. The source die 201 is flipped and placed on the desired portion of the surface of the target wafer, via step 108. Flip-chip technology may be used to carry out steps 106 and 108.

FIG. 2B depicts the semiconductor device 200 after step 108 is performed. Thus, a target wafer 220 is shown. The target wafer 220 may include the underlying Si wafer/substrate as well as any devices formed. The source die 201 has been flipped such that the active semiconductor element(s) 206 are between the surface of the target wafer 220 and the substrate 202. The bonding agent 210 is between the source die 201 and the target wafer 220. In the embodiment shown, the bonding agent 210 does not extend past the edges of the source die 201. However, in other embodiments, the bonding agent 210 extends over a larger area of the target wafer 220 surface than the source die 201. Alternatively, the bonding agent 210 may extend over an area smaller than the source die 201. For example, the bonding agent 210 may cover an area larger or smaller than the source die 201 by not more than fifty micrometers per side.

The source die 201 is bonded to the surface of the target wafer 220 using the bonding agent 210, via step 110. Step 110 includes exerting a force on the source die 201 and/or the target wafer 220 so that the thickness of the bonding agent 210 is as desired. In some embodiments, the force applied is at least 0.1 kg/cm² and not more than 0.6 kg/cm². The bonding agent 210 may also be at least partially cured by raising the temperature of the target wafer 220 and/or source die 201. For example, while the maximum force is being exerted on the source die 201 to set the bond thickness, the temperature of the source die 201 may be raised to at least one hundred degrees Celsius and not more than three hundred degrees Celsius. In some embodiments, the temperature is raised to at least one hundred seventy-five degrees Celsius and not more than two hundred and fifty degrees Celsius. This curing helps to ensure that the source die 201 remains stable at the selected location on the target wafer 220. Step 110 thus at least initiates chemical modification of the bonding material. If no other source dies are desired to be bonded to the target substrate, then step 110 may complete chemical conversion of the bonding agent, for example by raising the temperature to two hundred to four hundred degrees Celsius. In such embodiments, step 110 completely cures the bonding agent.

Steps 102 through 110 are optionally repeated for other source die(s), via step 112. Thus, multiple source dies may be integrated with the target wafer. An additional cure may be performed after all of the source dies are bonded to the target wafer, via step 114. The additional cure may raise the temperature to at least two hundred degrees Celsius and not more than four hundred degrees Celsius. Such an additional cure ensures complete chemical conversion of the bonding material. In some embodiments, all of the source dies to be integrated into the semiconductor device are bonded at the same level. Thus, steps 102 through 110 are completed on the same surface of the target wafer 220. In other embodiments, source dies might be integrated with the target wafer 220 at different levels. In such embodiments, step 112 may be performed after step 118 and may include steps 102 through 110, 114, 116 and 118 (discussed below).

The CS substrate 202 of the source die 201 is removed, including using the plasma etch to which the etch stop layer 204 is resistant, via step 116. Removal of the substrate 202 may include multiple sub-steps. Thus, other steps may be performed in addition to the plasma etch. For example, mechanical and/or chemical processes may be employed to reduce the thickness of the substrate 202 prior to the plasma etch. In some embodiments, the reduced thickness of the substrate 202 is between five micrometers and twenty micrometers. Prior to removal of the substrate 202, a temporary protective material may be applied across the surface of the target wafer 220. Application of such a protective material may be desired if only a single source die 210 is incorporated or if the source dies are widely spaced. Such a protective material may be used to safeguard the components on the target wafer 220 from the mechanical and chemical thinning processes. This protective material may be a photoresist, a more protective polymer such as polyimide, or Bismaleimide, epoxy, BCB, or other material that may protect the target wafer 220 surface in a rapid low cost manner. In some embodiments, an SOG might also be used as this protective layer. However, such an SOG is generally applied before the final curing step. An oxygen plasma may be used to remove any remaining polymeric protective materials after the grinding is completed. Other removal processes may be used for other protective materials. A plasma etch is then employed to complete removal of the substrate 202. For example, a plasma of SF₆/BCl₄ or SF₆/SiCl₄ may be used to remove remaining GaAs substrate.

FIG. 2C depicts the semiconductor device 200 after step 116 is performed. Thus, the bonding agent 210 has been converted to bond 210′ after step 112. In addition, the substrate 202 has been removed in step 116. Because it is resistant to the plasma etch, most or all of the etch stop layer 204 remains.

The etch stop layer 204 may optionally be removed, via step 118. An oxidation or selective wet etch may be performed in step 118. For example, for an AlGaAs layer, a wet etch such as a sulfuric acid based solution may remove the AlGaAs layer. FIG. 2D depicts the semiconductor device 200 after step 118 is performed. Thus, the etch stop layer 204 has been removed. Fabrication of the semiconductor device 200 may be completed, via step 119. For example, additional processing may be performed on the active semiconductor element(s) 206. If the active semiconductor element(s) include one or more layers, photolithography may be used to pattern the active semiconductor element(s) into one or more devices. Electrical contact may be made to the active semiconductor elements. Additional components/layers for the semiconductor device 200 may also be fabricated.

The method 100 may provide a semiconductor device incorporating heterogeneous elements, including silicon and active semiconductor elements with high interconnect density. For example, photonic components may be more readily integrated into semiconductor devices. The back end of line (BEOL) integration of the source die 201 does not interfere with fabrication of front end of line (FEOL) electronics on the target wafer 220 or with fabrication of the active semiconductor element(s) 206. For example, very thin epitaxial layers of III-V materials in the active semiconductor elements 206 may be incorporated into the semiconductor device 200. The method 100 may provide tight coupling with the electronics, allow for integration with deposited photonic structures (active semiconductor structures 206) in the BEOL and provide wafer level application that can be applied to various sized application specific integrated circuits (ASICs) or readout integrated circuits (ROICs). Further, because additional processing can be performed on the active semiconductor elements 206, metal contact structure can be made to the back side of the heterogeneous devices, deposited waveguides may be added after removal of the substrate 202, and/or other fabrication techniques can be applied. Because only the source dies 201 (as opposed to the entire source wafer) are bonded with the target substrate, the cost of integration and material waste may be reduced. Stated differently, the usable surface area of the target substrate 210 and materials used in the source die 201 may be optimized. The placement of the bonding agent 210 may also be optimized. Thus, processing is simplified and impact on subsequent processes may be reduced. Alignment of the source die 201 to the target wafer 220 may also be improved because of the use of existing alignment features of the target wafer 220. The method 100 may integrate active semiconductor elements 206 with components on a target wafer 220 in a manner that controls signal parasitics, manages power requirements and reduces packaging complexity. For example, the integration III-Nitride materials on the source die 201 into the semiconductor device 200 may enable a wide range of devices and systems from high power/high voltage analog and digital transistors to RF and Optical components.

The use of the method 100 may also allow for more complex system level topologies. Multiple regions of material or circuitry for source dies can be bonded to different areas of the target wafer's surface. This approach is even compatible with a flip chip bumped integration approach where subsequent layers of microbumps are placed on an earlier hybridized layer to allow for very complex, highly integrated system on chip components. For example, system level functions for optical data communications may be integrated using the method 100. In these cases, lower cost silicon CMOS or BCD may be used as the target wafer 220, providing tuning, interface, and control functions for the photonic elements in the source die 201 and signal routing for high-speed signals. A higher speed application specific logic circuit and photonic die could then be integrated to the front side using microbumps. This approach may allow the complex printed circuit board routing of signals to be moved to a more controlled environment while simplifying the overall architecture of the packaged component. This may provide a device having lower cost, higher data rate optical data links and active optical cables. Thus, the method 100 may improve integration of heterogeneous elements in a semiconductor device.

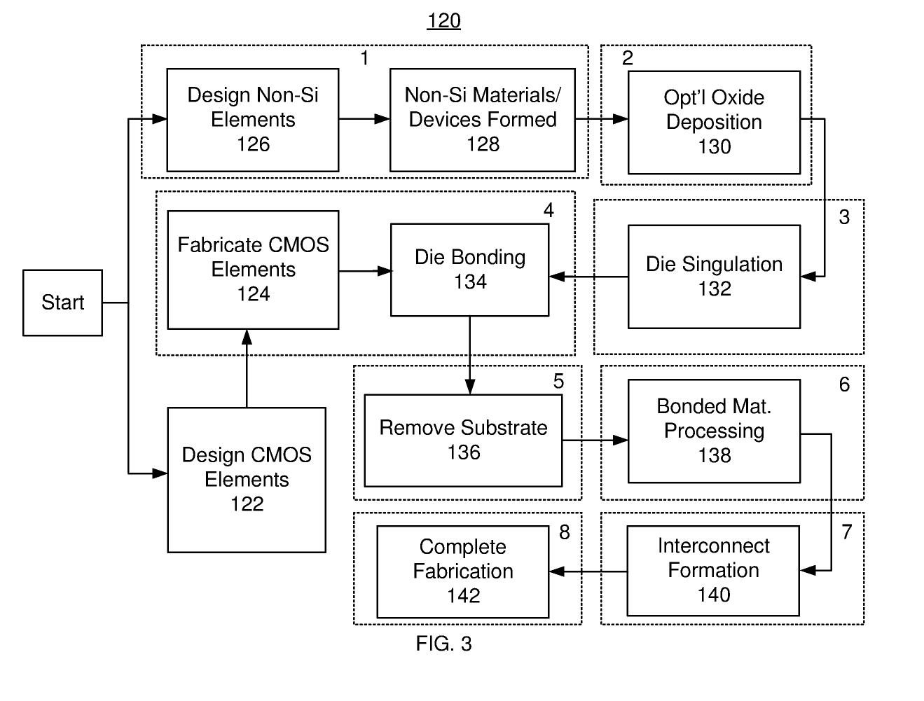

FIG. 3 is a flow chart depicting an exemplary embodiment of a method 120 for integrating heterogeneous elements in a semiconductor device, such as a CMOS device. More specifically, the method 120 integrates silicon elements with active semiconductor elements, as defined herein. For simplicity, some steps may be omitted, performed in another order and/or combined. FIG. 3 is also described in the context of a source die including GaAs as the CS substrate.

The semiconductor components for the semiconductor device are designed, via step 122. In the embodiment shown, CMOS elements are designed. In some embodiments, the elements both below (closer to the target substrate), on the same level as and above (further from the target substrate than) the active semiconductor element(s) to be integrated are designed. The CMOS elements that lie below the level at which the source die is to be integrated are fabricated in step 124.

The active semiconductor elements for the semiconductor device are designed, via step 126. Using this design, the active semiconductor elements are fabricated on the GaAs wafer(s), via step 128. Step 128 includes depositing or growing an etch stop layer such as AlGaAs on GaAs source substrate(s). The etch stop layer is resistant to a plasma etch for the GaAs wafer. Active semiconductor elements are formed on the etch stop layer. For example, III-V materials and/or III-Nitride may be grown epitaxially or otherwise on the etch stop layer. The layer(s) of the desired materials may be thin and may simply be left unprocessed. Alternatively, devices including the active semiconductor material(s) may be fabricated. Thus, any components and/or material(s) above the etch stop layer are considered the active semiconductor elements to be incorporated into the semiconductor device. Thus, through steps 126 and 128 in block 1, the active semiconductor elements are designed and grown on the GaAs source wafer(s).

A thin oxide such as silicon dioxide or other layer is optionally deposited on the surface of the source wafer(s), via step 130. In some embodiments, the oxide layer deposited is at least five nanometers thick. The oxide layer may be at least ten nanometers thick. In some such embodiments, the oxide layer is at least five and not more than two hundred nanometers thick. The oxide layer may improve bonding of the source die(s). The oxide layer deposited in step 130 might also be used to protect the active semiconductor elements from damage during singulation of the source wafer(s). Alternatively, a temporary material may be provided to prevent the incorporation of saw debris at the surface of the source die(s). However, if other singulation methods such as a scriber or laser are used to dice the wafer, such a protective layer may be omitted. Block 2 may thus be viewed as preparing the source wafer(s) and for singulation into the source dies.

The GaAs wafer(s) are then divided into individual dies, via step 132. Step 132 may be performed using a saw, scriber, laser or other mechanism for separating individual source dies from the wafer. The source die(s) singulated in step 132 are each smaller than the target wafer to which the source die(s) are to be bonded. Further, not all of the source dies from a single source in steps 126 through 132 may be bonded to the same target substrate. Instead, dies from a single wafer may be incorporated into multiple semiconductor devices. Alternatively, multiple source dies from the same source wafer may be integrated into a single semiconductor device. Conversely, multiple source dies from different source wafers may be integrated into a single semiconductor device. Block 3 may thus be viewed as performing source die singulation.

The target wafer including CMOS elements from step 124 and the source die(s) from step 132 are bonded together via step 134. As used herein, the target wafer may include both the underlying substrate/wafer and the devices formed thereon prior to bonding. Block 4 may thus be viewed as preparing the target wafer and bonding.

Step 134 includes applying the bonding agent to a portion of the surface of the target wafer. In some embodiments, the bonding agent is an SOG. The SOG may be applied via inkjet printing or nano-dispense tools. These application methods may reduce overspray and allow fine control of bonding agent thickness while reducing the volume of bonding agent needed. Alternatively, the bonding agent may be applied in a standard wafer track or bowl spinner. Commercially available SOGs or other bonding agents may be used. Such bonding agents provide a chemical path to conversion to a dielectric consistent with the silicon oxide or nitrides. For example, the bonding agent may be selected from The Honeywell Electronic Materials Accuglass Family of materials (T-11, T-12B, T-14, T-30, PTTY, P5S and newer Spin on Glasses); Filmtronics Spin on Glass products including 15A, 20B, P-15A, P-20B, 100F, 500F, x15F, x1F, 200F, 300F, 400F, 550F, 700F, 70F, 150F, 600f spin on glass and dielectrics; DOW Corning's Fox-1x and Fox-2x spin on dielectrics; Desert Silicon's silicon based Spin on glasses and Spin on Titanium oxide coatings such as SOG Ti-100 and SOG Ti-452; or other analogous SOG. Alternatively, other flowable dielectric coating(s) having an elevated temperature conversion may be used. In some embodiments, the SOG is at least one hundred nanometers thick and not more than five hundred nanometers thick. Other thicknesses are, however, possible. Use of SOG as a bonding agent may allow the bonding of two surfaces (of the source dies and target wafer) without the added requirement that the surfaces are ultra-planar, without modification using surface etching or modification, and/or without requiring use of other intermediate layers.

Other flowable bonding agents and/or application methods may be used. The bonding agent covers only a portion of the surface of the target wafer to which the source die(s) are desired to be bonded. In some embodiments, the bonding agent does not extend past the edges of desired location of a source die. In other embodiments, the bonding agent extends over a larger area of the target wafer surface than the source die by up to fifty micrometers per side. Alternatively, the bonding agent may extend over an area smaller than the source die up to fifty micrometers per side.

Step 134 also includes aligning the source die(s) to the desired location(s), flipping the source die(s) such that the substrate is furthest from the surface of the target wafer and placing the flipped source die(s) on to the surface of the target wafer. The alignment may use existing alignment features on the target wafer for precision alignment of the structure(s) on the source die(s) to existing structures on the target wafer. A force may be exerted on each source die to set the thickness of the bonding agent. In some embodiments, the force applied is at least 0.1 kg/cm² and not more than 0.6 kg/cm². In some embodiments, the average thickness of the bonding agent is at least ten nanometers and not more than one thousand nanometers. The die temperature is raised while the maximum force is being exerted on the source die to ensure that the placement of the source die is stabilized. The temperature of the source die may be raised to at least one hundred degrees Celsius and not more than three hundred degrees Celsius. This improves the stability of the source dies during fabrication. The process continues until all source die(s) to be bonded to the surface of the target wafer are bonded. In some embodiments, source die(s) may be incorporated at different levels. In such a case, steps 136-138 may be performed and additional CMOS elements may be fabricated in step 124 before bonding of additional source die(s) in step 134. Step 134 may perform an additional cure may be performed after all of the source dies are placed on the target wafer. Such an additional cure ensures complete chemical conversion of the bonding material. This additional cure may be performed by transferring the target wafer to a rapid thermal processing (RTP) tool and raising the temperature to at least two hundred degrees Celsius and not more than four hundred degrees Celsius. Thus, bonding of the source die(s) may be completed.

Block 5 and step 136 prepare and carry out GaAs substrate removal for the source dies that have been bonded to the target wafer. A protective material may thus be provided between the source dies to ensure the reliability of the source die edge. Thus, damage to the active semiconductor elements on the source die and elements on the target substrate during substrate removal may be reduced or eliminated. Examples of some protective materials are provided above. Step 136 also removes the GaAs substrate of the source die and, in some embodiments, the AIGaAs etch stop layer. Mechanical and/or chemical processes may be employed to reduce the thickness of the GaAs substrate. Remaining protective materials may be removed after the grinding is completed. A SF₆/BCl₄ or SF₆/SiCl₄ plasma etch may then be employed to complete removal of the GaAs substrate.

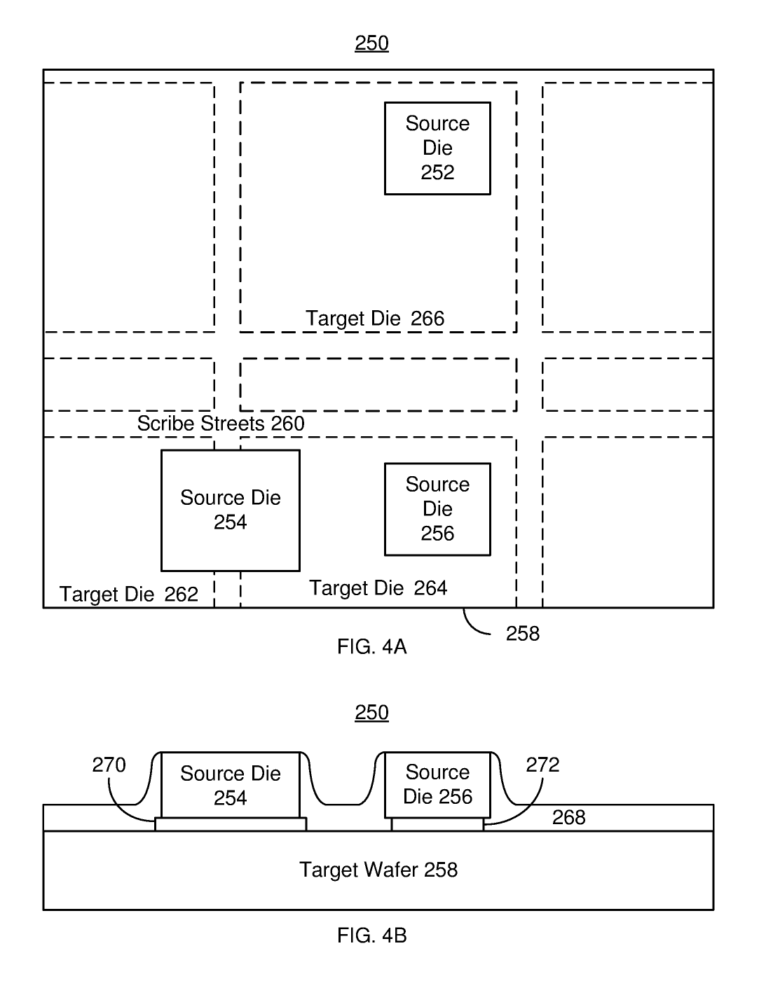

For example, FIGS. 4A and 4B depict a plan view and a side view, respectively, of an exemplary embodiment of a semiconductor device 250 that integrates heterogeneous elements. For simplicity, not all components are shown in FIGS. 4A-4B and FIGS. 4A-4B are not to scale. As can be seen in FIG. 4A, source dies 252, 254 and 256 have been placed on the top surface of the target wafer 258. The source dies 252, 254 and 256 have varying sizes which are less than that of the target wafer 258 and may be less than the size of the wafer(s) from which the source dies 252, 254 and 256 were formed. As can be seen in FIG. 4B, bonding agent 270 and 272 is between the source dies 252 and 254 and the target wafer 258. The bonding agent 270 is larger than the source die 254, while the bonding agent 272 has a smaller footprint than the source die 256. Also shown in FIG. 4B is protective material 268 that has been applied between the source dies 254 and 256.

The AIGaAs etch stop layer may optionally be removed as part of step 136. For example, the AIGaAs etch stop layer may be removed by a wet etch including but not limited to a sulfuric acid based Piranha etch or modifications such as a dilute form or H₂SO₄:H₂O₂:H₂O; which allows control over the removal rate. A simple HF or buffered HF solution can also be used to remove the Al containing etch stop with sufficient selectivity.

The materials on the source dies that have been bonded to the target wafer may undergo additional processing, via step 138 of block 6. For example, additional processing may be performed on the active semiconductor elements. Electrical interconnections are formed from the active semiconductor elements to the target substrate or to allow electrical functionality/test of the fabricated structures/devices, via step 140 of block 7. Fabrication of the semiconductor device may be completed, via step 142. For example, additional component may be fabricated on and/or around the active semiconductor elements.

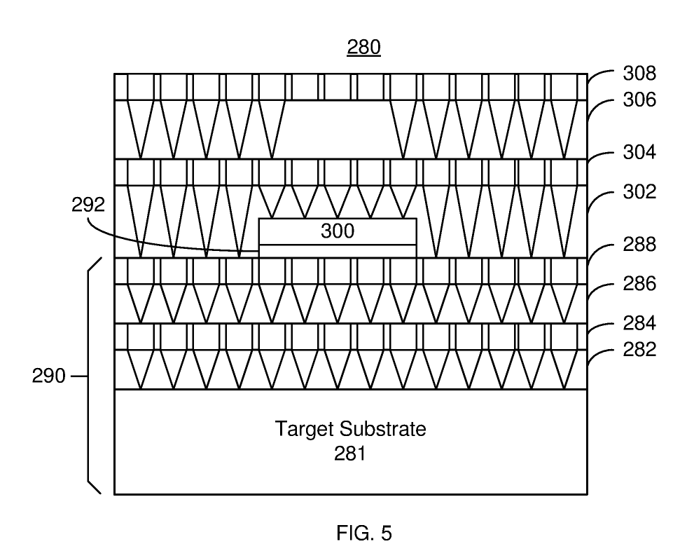

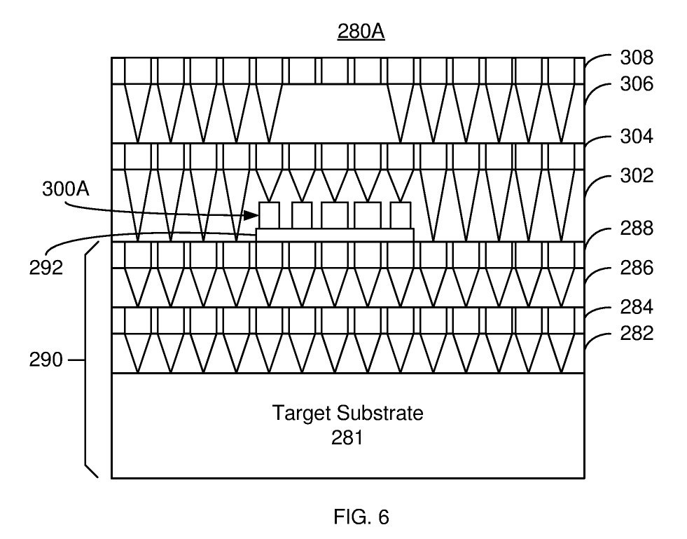

FIGS. 5 and 6 depict embodiments of semiconductor devices 280 and 280A formed using the method 120. For simplicity, not all components are shown in FIGS. 5-6 and FIGS. 5-6 are not to scale. Referring to FIG. 5, the semiconductor device 280 is formed on a target substrate 281 that may be Si. Structures (not shown) may be formed in the target substrate 281. In addition, various layers 282, 284, 286, 288, 302, 304, 306 and 308 have been formed on the target substrate 281. Although indicated as having particular structures, in other embodiments, different and/or additional structures as well as different and/or additional layers may be provided. The contact via layer 282, metal 1 layer 284, via 1 layer 286 and metal 2 layer 288 are formed prior to bonding of the active semiconductor elements 300. Thus, the target substrate 281 and layers 282, 284, 286 and 288 may be considered part of the target wafer 290. Bonding agent/bond 292 and active semiconductor elements 300 are shown. The active semiconductor elements may be simple layer(s) or fabricated structures. Such structures may be formed prior to bonding of the source die that including a GaAs substrate (previously removed/not shown) and active semiconductor elements 300. Dual via depth layer 302, metal layer 3 304, via layer 3 306 and metal layer 308. The layers 302, 304, 306 and 308 may be fabricated after bonding of the source die with the target wafer 290. Although various specific layers 282, 284, 286, 288, 302, 304, 306 and 308 have been described, additional and/or other layers may be present.

FIG. 6 includes semiconductor device 280A analogous to the semiconductor device 280 depicted in FIG. 5. Consequently, analogous structures have similar labels. The semiconductor device 280A thus includes target substrate 281, bonding agent/bond 292, active semiconductor elements 300A and layers 282, 284, 286, 288, 302, 304, 306 and 308 corresponding to components 281, bonding agent/bond 292, active semiconductor elements 300 and layers 282, 284, 286, 288, 302, 304, 306 and 308 of the semiconductor device 280. However, the individual active semiconductor devices 300A are explicitly shown as individuated. Thus, the active semiconductor elements 300 and 300A may be incorporated into the semiconductor devices 280 and 280A using the method 120.

The method 120 shares the benefits of the method 100. Thus, the method 120 may improve integration of heterogeneous elements in a semiconductor device.

Various features have been described with respect to the methods 100 and 120 and the devices 200, 250, 280 and 280A. One of ordinary skill in the art will recognize that these features may be combined in manner(s) not shown and which are not inconsistent with the devices and methods described herein.

A method and system for integrating heterogeneous elements into semiconductor devices have been described. The method and system have been described in accordance with the exemplary embodiments shown, and one of ordinary skill in the art will readily recognize that there could be variations to the embodiments, and any variations would be within the spirit and scope of the method and system. Accordingly, many modifications may be made by one of ordinary skill in the art without departing from the spirit and scope of the appended claims.

We claim:

1. A method for integrating heterogeneous elements with circuit elements residing on a target wafer comprising:
providing a source die including a compound semiconductor (CS) substrate, an etch stop layer and at least one active semiconductor element, the etch stop layer residing between the at least one active semiconductor element and the CS substrate, the etch stop layer being resistant to a plasma etch for removing the CS substrate;
providing a bonding agent on at least a portion of a surface of the target wafer;
aligning the source die to the portion of the surface of the target wafer;
placing the source die on the portion of the surface of the target wafer such that the at least one active semiconductor element is between the surface of the target wafer and the CS substrate, at least a portion of the bonding agent residing between the source die and the surface of the target wafer;
bonding the source die to the surface of the target wafer using the bonding agent; and
removing the CS substrate of the source, a portion of the removing step including performing the plasma etch.

2. The method of claim 1 further comprising:
removing the etch stop layer.

3. The method of claim 1 further comprising:
performing additional processing on the at least one active semiconductor element after the step of curing the bonding agent.

4. The method of claim 1 wherein the at least one active semiconductor element includes at least one of a quantum well, a quantum dot, a quantum wire, at least one layer of epitaxial material, at least one III-V material and at least one III-Nitride material.

5. The method of claim 1 wherein the surface of the target wafer includes a plurality of scribe streets and wherein step of aligning the source die includes aligning the source die across at least one of the plurality of scribe streets.

6. The method of claim 1 wherein the step of providing the source die includes:
providing the etch stop layer and the at least one active semiconductor element on a source wafer; and
singulating the source wafer into a plurality of dies including the source die.

7. The method of claim 6 wherein the step of providing the source die further includes:
depositing an oxide layer on the source wafer after formation of the at least one heterogenous element and before the step of singulating the source wafer

8. The method of claim 1 wherein CS substrate is a GaAs substrate and wherein the etch stop layer is an AIGaAs layer.

9. The method of claim 9 wherein the step of removing the CS substrate further includes:
reducing a thickness of the CS substrate using at least one of mechanical and chemical processes; and
plasma etching a remaining portion of the CS substrate.

10. The method of claim 1 wherein the bonding agent is a spin-on glass (SOG) and wherein the step of providing the bonding agent includes:
applying the SOG with an application method selected from inkjet printing, utilizing nano-dispense tools and a spin-on application.

11. The method of claim 1 further comprising:
electrically coupling the at least one active semiconductor element with at least one circuit component.

12. The method of claim 1 wherein the step of bonding the source die to the target wafer further includes:
applying a force to at least one of the source die and the target wafer such that the bonding agent has a bond thickness;
initiating curing of the bonding agent.

13. The method of claim 12 further comprising:
repeating the source die providing, bonding agent providing, aligning, placing the source die and force applying step for at least one additional source die.

14. The method of claim 13 further comprising:
repeating the bonding step for the at least one additional source die.

15. The method of claim 14 further comprising:
performing an additional curing step for the bonding agent for the source die and the at least one additional source die.

16. The method of claim 13 wherein the bonding step cures the bonding agent for the source die and the at least one additional source die and wherein the CS substrate removing step also removes at least one additional source die CS substrate for the at least one additional source die.

17. The method of claim 1 further comprising:
fabricating additional components on the target wafer after the step of removing the CS substrate.

18. The method of claim 1 further comprising:
fabricating additional components on the target wafer before the step of aligning the source die to the portion of the surface of the target wafer.

19. A method for integrating heterogeneous elements with circuit elements residing on a target wafer comprising:
providing a source die including a GaAs substrate, an AIGaAs etch stop layer and at least one active semiconductor element, the AIGaAs etch stop layer residing between the at least one active semiconductor element and the GaAs substrate;
applying a spin-on glass (SOG) bonding agent on at least a portion of a surface of the target wafer;
aligning the source die to the portion of surface of the target wafer;
placing the source die on the portion of the surface of the target wafer such that the at least one active semiconductor element is between the surface of the target wafer and the GaAs substrate, at least a portion of the SOG bonding agent residing between the source die and the surface of the target wafer;
applying a force to at least one of the source die and the target wafer such that the SOG bonding agent has a bond thickness;
heating at least the SOG bonding agent to a temperature of at least two hundred degrees Celsius and not more than four hundred degrees Celsius;
applying a protective layer to at least a side of the source die;
removing the GaAs substrate of the source die, the step of removing the GaAs substrate including
reducing a thickness of the GaAs substrate using at least one of mechanical and chemical processes; and
performing a plasma etch of a remaining portion of the GaAs substrate, the AIGaAs etch stop layer being a stop layer for the plasma etch;
wet etching the AIGaAs etch stop layer after the plasma etch; and
at least one of performing additional processing on the at least one active semiconductor element and providing additional components on the target wafer.

20. A semiconductor device including a target substrate and comprising:
a plurality of components fabricated on the target substrate;
at least one active semiconductor element integrated with the plurality of components on the target substrate, a bonding agent residing between the active semiconductor element and a portion of the target substrate, the at least one active semiconductor element being provided from a source die including a compound semiconductor (CS) substrate, an etch stop layer and at least one active semiconductor element precursor, the etch stop layer residing between the at least one active semiconductor element and the CS substrate, the etch stop layer being resistant to a plasma etch for the CS substrate, the source die being singulated prior to being bonded to the target substrate, source die being integrated into the semiconductor device by providing the bonding agent on at least a portion of a surface of a target wafer including the target substrate, aligning the source die to the portion of the surface of the target wafer, placing the source die on the portion of the surface of the target wafer such that the at least one active semiconductor element precursor is between the surface of the target wafer and the CS substrate, applying a force to at least one of the source die and the target wafer such that the bonding agent has a bond thickness, curing the bonding agent and removing the CS substrate of the source die using the removal process, the at least one active semiconductor element precursor being the at least one active semiconductor element or a portion of the at least one active semiconductor element.
